(19) United States
(12) Patent Application Publication
(10) Pub. No.: US 2026/0220767 A1
(43) Pub. Date: Jul. 30, 2026

(54) MASK CALIBRATION METHOD FOR MASK DEFECT DETECTION

(71) Applicant: CHANGZHOU VIP SEMICONDUCTOR EQUIPMENT CO., LTD, Changzhou (CN)

(72) Inventor: Dongliang XU, Changzhou (CN)

(73) Assignee: CHANGZHOU VIP SEMICONDUCTOR EQUIPMENT CO., LTD, Changzhou (CN)

(21) Appl. No.: 19/577,702

(22) Filed: Mar. 25, 2026

Related U.S. Application Data
(63) Continuation of application No. PCT/CN2025/119272, filed on Sep. 5, 2025.

(30) Foreign Application Priority Data
Jan. 24, 2025 (CN) 202510114126.X

(51) Int. Cl. G06T 7/00; G03F 1/84; G03F 7/00; G06T 3/403; G06T 7/13; G06T 7/30

(52) U.S. Cl. CPC G06T 7/001; G03F 1/84; G03F 7/70508; G03F 7/70516; G06T 3/403; G06T 7/13; G06T 7/30; G06T 2207/30148

(57) ABSTRACT

A mask calibration method for mask defect detection includes: S1, choosing a selected area with a pattern in a mask design file, and outputting vector points of the selected area; S2, using an automated optical inspection (AOI) device to acquire an actual image of a corresponding physical mask that corresponds to the selected area; and S3, setting a horizontal tolerance range in a horizontal direction of the selected area, and performing step S31: using different horizontal tolerance compensation values within the horizontal tolerance range to respectively fill and render the vector points output in step S1 into first rendered images; respectively registering the first rendered images obtained by rendering with the different horizontal tolerance compensation values with the actual image, employing an evaluation method to evaluate influences of the different horizontal tolerance compensation values on degrees of fit between the first rendered images and the actual image.

### CROSS-REFERENCE TO RELATED APPLICATIONS

This application is a continuation of International Patent Application No. PCT/CN2025/119272 with a filing date of Sep. 5, 2025, designating the United States, now pending, and further claims priority to Chinese Patent Application No. 202510114126.X with a filing date of Jan. 24, 2025. The content of the aforementioned applications, including any intervening amendments thereto, is incorporated herein by reference.

### FIELD OF THE INVENTION

The present disclosure relates to a mask calibration method for mask defect detection.

### BACKGROUND OF THE INVENTION

At present, in the process of semiconductor mask defect detection, the DIE to DB (D2DB) mode is generally used for detection. That is, the picture of the physical mask finally produced is compared with the mask design file to identify defects. However, in the process of mask lithography, due to the difference in process level, there are certain tolerances in the pattern size of the manufactured mask. These tolerances will lead to the appearance of false defects during the subsequent defect detection. Thus, it is sometimes more difficult to identify whether defects are true defects.

### SUMMARY OF THE INVENTION

The technical problem to be solved by the present disclosure is to overcome the defects of the prior art, and to provide a mask calibration method for mask defect detection, by which the precision and accuracy of defect detection can be improved.

In order to solve the above-mentioned technical problem, the present disclosure provides the following technical solution: a mask calibration method for mask defect detection includes the following steps:
S1, choosing a selected area with a pattern in a mask design file, and outputting vector points of the selected area;
S2, using an automated optical inspection (AOI) device to acquire an actual image of a corresponding physical mask that corresponds to the selected area;
S3, setting a horizontal tolerance range in a horizontal direction of the selected area, and performing step S31: using different horizontal tolerance compensation values within the horizontal tolerance range to respectively fill and render the vector points output in step S1 into first rendered images; respectively registering the first rendered images obtained by rendering with the different horizontal tolerance compensation values with the actual image, employing an evaluation method to evaluate influences of the different horizontal tolerance compensation values on degrees of fit between the first rendered images and the actual image, and taking as a calibrated tolerance in the horizontal direction a horizontal tolerance compensation value for which a best evaluation result is obtained; and
S4, setting a vertical tolerance range in a vertical direction of the selected area, and performing step S41: using different vertical tolerance compensation values within the vertical tolerance range to respectively fill and render the vector points output in step S1 into second rendered images; respectively registering the second rendered images obtained by rendering with the different vertical tolerance compensation values with the actual image, employing an evaluation method to evaluate influences of the different vertical tolerance compensation values on degrees of fit between the second rendered images and the actual image, and taking as a calibrated tolerance in the vertical direction a vertical tolerance compensation value for which a best evaluation result is obtained.

Further, in order to obtain a more accurate horizontal tolerance compensation value, in step S3, the horizontal tolerance compensation value for which the best evaluation result is obtained is taken as a calibrated horizontal tolerance range for a second evaluation, and step S31 is repeated to obtain a final calibrated tolerance in the horizontal direction.

Further, in order to obtain a more accurate vertical tolerance compensation value, in step S4, the vertical tolerance compensation value for which the best evaluation result is obtained is taken as a calibrated vertical tolerance range for a second evaluation, and step S41 is repeated to obtain a final calibrated tolerance in the vertical direction.

Further, in step S3, the evaluation method specifically includes:
obtaining vertical edges of the first rendered image and the actual image;
calibrating a vertical edge region based on the vertical edges;
calculating a first difference value sum, namely a first error sum, of the first rendered image and the actual image in the vertical edge region; and
taking as the calibrated tolerance in the horizontal direction a corresponding horizontal tolerance compensation value obtained with an evaluation objective to minimize the first difference value sum.

The obtaining vertical edges of the first rendered image and the actual image specifically includes: performing horizontal differentiation on the first rendered image or the actual image, setting a horizontal differentiation threshold, and marking as the vertical edge a region where the horizontal differentiation is greater than the horizontal differentiation threshold and vertical differentiation is close to 0.

Further, the calibrating a vertical edge region based on the vertical edges specifically includes: setting the vertical edge region to be within a set number of pixels adjacent to the vertical edges.

Further, in order to obtain a more accurate horizontal tolerance compensation value, a minimum first difference value sum is obtained by fitting between the horizontal tolerance compensation value and the first difference value sum.

Further, in step S4, the evaluation method specifically includes:
obtaining horizontal edges of the second rendered image and the actual image;
calibrating a horizontal edge region based on the horizontal edges;
calculating a second difference value sum, namely a second error sum, of the second rendered image and the actual image in the horizontal edge region; and
taking as the calibrated tolerance in the vertical direction a corresponding vertical tolerance compensation value obtained with an evaluation objective to minimize the second difference value sum.

Further, the obtaining horizontal edges of the second rendered image and the actual image specifically includes: performing vertical differentiation on the second rendered image or the actual image, setting a vertical differentiation threshold, and marking as the horizontal edge a region where the vertical differentiation is greater than the vertical differentiation threshold and horizontal differentiation is close to 0.

Further, the calibrating a horizontal edge region based on the horizontal edges specifically includes: setting the horizontal edge region to be within a set number of pixels adjacent to the horizontal edges.

Further, in order to obtain a more accurate vertical tolerance compensation value, a minimum second difference value sum is obtained by fitting between the vertical tolerance compensation value and the second difference value sum.

Further, the rendering in step S3 and step S4 specifically includes the following steps:
performing size scaling on a pattern corresponding to the vector points according to a tolerance compensation value;
then performing sub-pixel edge filling on the corrected vector points; and
correcting the filled pattern using a selected model to obtain a corresponding rendered image.

With the above technical solutions, the calibration method provided in the present disclosure can achieve high-precision detection on the mask within an allowable tolerance range without causing a large number of false defects. Furthermore, the method of the present disclosure provides for the calibration in the horizontal and vertical directions respectively so that the tolerances in the two dimensions are independent and do not affect each other to result in incorrect calibrated tolerances. Moreover, only the information of the vertical edge and the horizontal edge is processed, and the noise caused by a large number of corners can be ignored, thereby greatly improving the calibrated tolerances and the reliability. Second, the present disclosure involves evaluating the quality of the tolerance compensation values by means of the error sums, thereby reducing unnecessary noise caused by registration and improving the accuracy of calibration.

### BRIEF DESCRIPTION OF THE DRAWINGS

FIG. 1 is a vector point representation of a selected area in a mask design file, where the intersection points are the positions of points, and the dotted line is the polygon formed by connecting these points;

FIG. 2 (a) shows an actual image of a mask corresponding to the selected area in FIG. 1;

FIG. 2 (b) shows a low-pass filtered rendered image of the selected area in FIG. 1;

FIG. 3 (a) shows a difference image of an actual image and a rendered image without tolerance correction;

FIG. 3 (b) shows a difference image of an actual image and a tolerance corrected rendered image; and

FIG. 4 is a scatter plot of evaluation error results obtained by correcting different tolerances in the present disclosure.

### DETAILED DESCRIPTION OF PREFERRED EMBODIMENTS

To make the content of the present disclosure more readily and clearly understandable, the following describes the present disclosure in more detail with reference to specific embodiments and accompanying drawings.

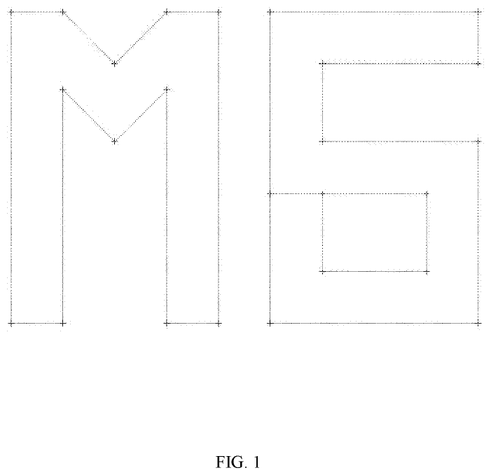

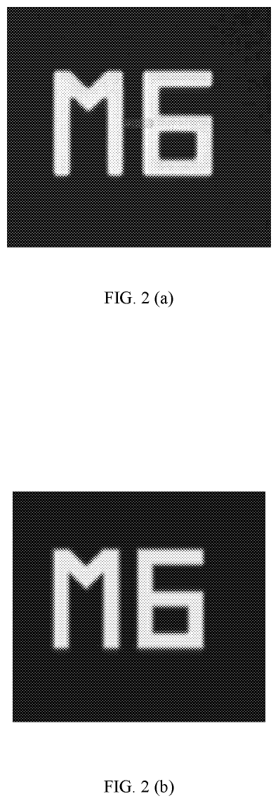

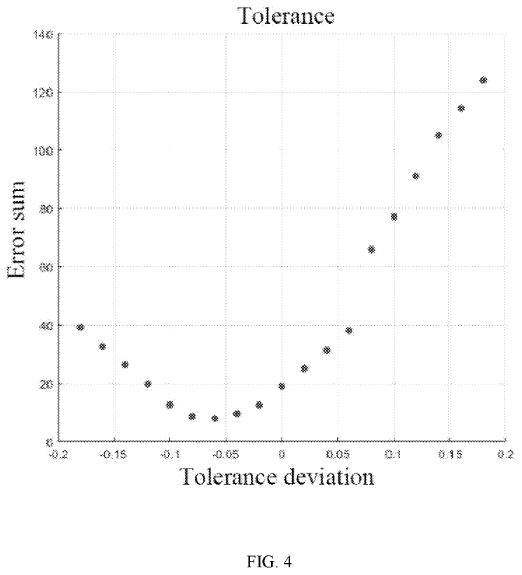

As shown in FIG. 1 to FIG. 4, a mask calibration method for mask defect detection includes the following steps:
S1, choosing, by electronic design automation (EDA) software, a selected area with a pattern in a mask design file, and outputting vector points of the selected area, as shown in FIG. 1;
S2, after aligning a corresponding physical mask using an AOI device, acquiring an actual image of the corresponding physical mask that corresponds to the selected area using a detection camera of the AOI device, as shown in FIG. 2 (a), where the purpose of the alignment is to perform a mapping between the platform coordinates of the AOI device and the coordinates of the mask design file, so as to acquire the actual image corresponding to the selected area marked in step S1;
S3, setting a horizontal tolerance range in a horizontal direction (i.e., X direction) of the selected area, and performing step S31: using different horizontal tolerance compensation values within the horizontal tolerance range to respectively fill and render the vector points output in step S1 into first rendered images; respectively registering the first rendered images obtained by rendering with the different horizontal tolerance compensation values with the actual image, employing an evaluation method to evaluate influences of the different horizontal tolerance compensation values on degrees of fit between the first rendered images and the actual image, and taking as a calibrated tolerance in the horizontal direction a horizontal tolerance compensation value for which a best evaluation result is obtained, where using different horizontal tolerance compensation values within the horizontal tolerance range specifically includes: uniformly selecting a plurality of suitable numerical points within the horizontal tolerance range, and taking these numerical points as the different horizontal tolerance compensation values; and
S4, setting a vertical tolerance range in a vertical direction (i.e., Y direction) of the selected area, and performing step S41: using different vertical tolerance compensation values within the vertical tolerance range to respectively fill and render the vector points output in step S1 into second rendered images; respectively registering the second rendered images obtained by rendering with the different vertical tolerance compensation values with the actual image, employing an evaluation method to evaluate influences of the different vertical tolerance compensation values on degrees of fit between the second rendered images and the actual image, and taking as a calibrated tolerance in the vertical direction a vertical tolerance compensation value for which a best evaluation result is obtained, where using different vertical tolerance compensation values within the vertical tolerance range specifically includes: uniformly selecting a plurality of suitable numerical points within the vertical tolerance range, and taking these numerical points as the different vertical tolerance compensation values.

In this embodiment, multithreading may be used in the processes of steps S3 and S4 to increase the calculation speed.

In this embodiment, phase registration may be used as the method of registration in steps S3 and S4 to achieve a sub-pixel level, thereby improving the registration precision.

Specifically, in order to obtain a more accurate horizontal tolerance compensation value, in step S3, the horizontal tolerance compensation value for which the best evaluation result is obtained is taken as a calibrated horizontal tolerance range for a second evaluation, and step S31 is repeated to obtain a final calibrated tolerance in the horizontal direction.

Specifically, in order to obtain a more accurate vertical tolerance compensation value, in step S4, the vertical tolerance compensation value for which the best evaluation result is obtained is taken as a calibrated vertical tolerance range for a second evaluation, and step S41 is repeated to obtain a final calibrated tolerance in the vertical direction.

Specifically, in step S3, the evaluation method specifically includes:
obtaining vertical edges of the first rendered image and the actual image;
calibrating a vertical edge region based on the vertical edges;
calculating a first difference value sum, namely a first error sum, of the first rendered image and the actual image in the vertical edge region; and
taking as the calibrated tolerance in the horizontal direction a corresponding horizontal tolerance compensation value obtained with an evaluation objective to minimize the first difference value sum.

Obtaining the vertical edges of the first rendered image and the actual image specifically includes: performing horizontal differentiation on the first rendered image or the actual image, setting a horizontal differentiation threshold, and marking as the vertical edge a region where the horizontal differentiation is greater than the horizontal differentiation threshold and vertical differentiation is close to 0 (which may be set according to the uniformity of light, and is generally less than 5).

Specifically, calibrating the vertical edge region based on the vertical edges specifically includes: setting the vertical edge region to be within a set number of pixels adjacent to the vertical edges. In this embodiment, the set number of pixels may be 3 pixels. Of course, other numbers may also be possible.

Specifically, in order to obtain a more accurate horizontal tolerance compensation value, a minimum first difference value sum is obtained by fitting between the horizontal tolerance compensation value and the first difference value sum.

Specifically, in step S4, the evaluation method specifically includes:
obtaining horizontal edges of the second rendered image and the actual image;
calibrating a horizontal edge region based on the horizontal edges;
calculating a second difference value sum, namely a second error sum, of the second rendered image and the actual image in the horizontal edge region; and
taking as the calibrated tolerance in the vertical direction a corresponding vertical tolerance compensation value obtained with an evaluation objective to minimize the second difference value sum.

Further, obtaining the horizontal edges of the second rendered image and the actual image specifically includes: performing vertical differentiation on the second rendered image or the actual image, setting a vertical differentiation threshold, and marking as the horizontal edge a region where the vertical differentiation is greater than the vertical differentiation threshold and horizontal differentiation is close to 0 (which may be set according to the uniformity of light, and is generally less than 5).

Specifically, calibrating the horizontal edge region based on the horizontal edges specifically includes: setting the horizontal edge region to be within a set number of pixels adjacent to the horizontal edges. In this embodiment, the set number of pixels may be 3 pixels. Of course, other numbers may also be possible.

Specifically, in order to obtain a more accurate vertical tolerance compensation value, a minimum second difference value sum is obtained by fitting between the vertical tolerance compensation value and the second difference value sum.

Specifically, the rendering in steps S3 and S4 is to render into a bitmap according to the point set of the mask design file. During the rendering process, it is necessary to use a corresponding model, such as a low-pass filter model, a scalar optical simulation model, and a vectorial optical simulation model, so as to approximate to the real mask acquisition, and the result of rendering is as shown in FIG. 2 (b). The particular method may be selected based on acceptable errors. According to the set tolerance range, the tolerance range is divided by a larger interval, and graphics rendering is performed once for each tolerance compensation value. The rendering in steps S3 and S4 specifically includes the following steps:
performing size scaling on a pattern corresponding to the vector points according to a tolerance compensation value;
then performing sub-pixel edge filling on the corrected vector points; and
correcting the filled pattern using a selected model to obtain a corresponding rendered image.

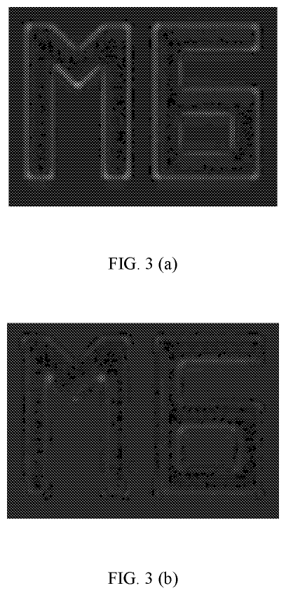

In this embodiment, the difference method in steps S3 and S4, i.e., by directly summing the difference values, can well neutralize the error caused by inaccurate registration, because the inaccurate registration tends to result in the opposite signs of the difference values of the symmetrical two edges of the pattern. If the tolerance value is correct, the sum of these difference values will be approximately equal to 0. Only in the case where a tolerance error is present, will there be a larger value, and the larger the deviation of the tolerance, the larger the value of the difference sum. This is why this difference method can be used to evaluate the quality of the tolerance compensation value in the horizontal direction or the vertical direction. Moreover, since only the error at the horizontal edge or the vertical edge is calculated with respect to the difference, the error at the corner is not accounted for. Especially, the error at the corner is ignored. Because the process level is more uncontrollable at the corner, the corner tends to provide a lot of noise information. Also because the difference is ascertained respectively horizontally and vertically, the tolerances in both the horizontal and vertical dimensions are separated very smartly, thus providing greater accuracy. As shown in FIG. 3 (a) and FIG. 3 (b), if tolerance compensation is not performed, there is a significant deviation between the rendered image and the actual image. After the mask layout is corrected with the tolerance compensation value calibrated using the minimum error, the rendered image and the actual image become more closely fitted with only a small deviation between them.

The technical problems solved by, technical solutions, and beneficial effects of the present disclosure are further described in detail in the above specific embodiments. It should be understood that the above are merely specific embodiments of the present disclosure, but are not intended to limit the present disclosure. Any modification, equivalent replacement, or improvement made within the spirit and principle of the present disclosure shall fall within the protection scope of the present disclosure.

What is claimed is

1. A mask calibration method for mask defect detection, comprising the following steps:
S1, choosing a selected area with a pattern in a mask design file, and outputting vector points of the selected area;
S2, using an automated optical inspection (AOI) device to acquire an actual image of a corresponding physical mask that corresponds to the selected area;
S3, setting a horizontal tolerance range in a horizontal direction of the selected area, and performing step S31: using different horizontal tolerance compensation values within the horizontal tolerance range to respectively fill and render the vector points output in step S1 into first rendered images; respectively registering the first rendered images obtained by rendering with the different horizontal tolerance compensation values with the actual image, employing an evaluation method to evaluate influences of the different horizontal tolerance compensation values on degrees of fit between the first rendered images and the actual image, and taking as a calibrated tolerance in the horizontal direction a horizontal tolerance compensation value for which a best evaluation result is obtained; and
S4, setting a vertical tolerance range in a vertical direction of the selected area, and performing step S41: using different vertical tolerance compensation values within the vertical tolerance range to respectively fill and render the vector points output in step S1 into second rendered images; respectively registering the second rendered images obtained by rendering with the different vertical tolerance compensation values with the actual image, employing an evaluation method to evaluate influences of the different vertical tolerance compensation values on degrees of fit between the second rendered images and the actual image, and taking as a calibrated tolerance in the vertical direction a vertical tolerance compensation value for which a best evaluation result is obtained.

2. The mask calibration method according to claim 1, wherein
in step S3, the horizontal tolerance compensation value for which the best evaluation result is obtained is taken as a calibrated horizontal tolerance range for a second evaluation, and step S31 is repeated to obtain a final calibrated tolerance in the horizontal direction.

3. The mask calibration method according to claim 1, wherein
in step S4, the vertical tolerance compensation value for which the best evaluation result is obtained is taken as a calibrated vertical tolerance range for a second evaluation, and step S41 is repeated to obtain a final calibrated tolerance in the vertical direction.

4. The mask calibration method according to claim 1, wherein in step S3, the evaluation method specifically comprises:
obtaining vertical edges of the first rendered image and the actual image;
calibrating a vertical edge region based on the vertical edges;
calculating a first difference value sum, namely a first error sum, of the first rendered image and the actual image in the vertical edge region; and
taking as the calibrated tolerance in the horizontal direction a corresponding horizontal tolerance compensation value obtained with an evaluation objective to minimize the first difference value sum.

5. The mask calibration method according to claim 4, wherein
the obtaining vertical edges of the first rendered image and the actual image specifically comprises: performing horizontal differentiation on the first rendered image or the actual image, setting a horizontal differentiation threshold, and marking as the vertical edge a region where the horizontal differentiation is greater than the horizontal differentiation threshold and vertical differentiation is close to 0; and
the calibrating a vertical edge region based on the vertical edges specifically comprises: setting the vertical edge region to be within a set number of pixels adjacent to the vertical edges.

6. The mask calibration method according to claim 4, wherein
a minimum first difference value sum is obtained by fitting between the horizontal tolerance compensation value and the first difference value sum.

7. The mask calibration method according to claim 1, wherein in step S4, the evaluation method specifically comprises:
obtaining horizontal edges of the second rendered image and the actual image;
calibrating a horizontal edge region based on the horizontal edges;
calculating a second difference value sum, namely a second error sum, of the second rendered image and the actual image in the horizontal edge region; and
taking as the calibrated tolerance in the vertical direction a corresponding vertical tolerance compensation value obtained with an evaluation objective to minimize the second difference value sum.

8. The mask calibration method according to claim 6, wherein
the obtaining horizontal edges of the second rendered image and the actual image specifically comprises: performing vertical differentiation on the second rendered image or the actual image, setting a vertical differentiation threshold, and marking as the horizontal edge a region where the vertical differentiation is greater than the vertical differentiation threshold and horizontal differentiation is close to 0; and
the calibrating a horizontal edge region based on the horizontal edges specifically comprises: setting the horizontal edge region to be within a set number of pixels adjacent to the horizontal edges.

9. The mask calibration method according to claim 7, wherein
a minimum second difference value sum is obtained by fitting between the vertical tolerance compensation value and the second difference value sum.

10. The mask calibration method according to claim 1, wherein
the rendering in step S3 and step S4 specifically comprises the following steps:
performing size scaling on a pattern corresponding to the vector points according to a tolerance compensation value;
then performing sub-pixel edge filling on the corrected vector points; and
correcting the filled pattern using a selected model to obtain a corresponding rendered image.
